(19) United States
(12) Patent Application Publication
(10) Pub. No.: US 2025/0089571 A1
(43) Pub. Date: Mar. 13, 2025

(54) Formation of Film Stacks with Active Film Layers

(71) Applicant: Applied Materials, Inc., Santa Clara, CA (US)

(72) Inventors: Xiaodong YANG, Xi'an (CN); Lizhong SUN, San Jose, CA (US)

(21) Appl. No.: 18/398,588

(22) Filed: Dec. 28, 2023

(30) Foreign Application Priority Data
Sep. 11, 2023 (WO) PCT/CN2023/118049

(51) Int. Cl. H10N 30/079; H10N 30/00; H10N 30/076; H10N 30/853

(52) U.S. Cl. CPC H10N 30/079; H10N 30/076; H10N 30/704; H10N 30/853

(57) ABSTRACT

A method for forming and a film stack for a piezoelectric device includes a first seed layer of aluminum nitride, aluminum oxide, or silicon nitride formed on a substrate, an intermediate film layer formed on the first seed layer at a temperature of approximately 300 degrees Celsius to approximately 400 degrees Celsius where the intermediate film layer includes a first layer of a first material and a second layer of a second material that is different from the first material, a second seed layer of aluminum nitride, aluminum oxide, or silicon nitride formed on the intermediate film layer, and an active film layer with a full width half maximum (FWHM) of 1.2 degrees or less formed on the second seed layer.

### CROSS-REFERENCE TO RELATED APPLICATIONS

This application claims the benefit of Patent Cooperation Treaty Application PCT/CN2023/118049, filed on 11 Sep. 2023, which is herein incorporated by reference in its entirety.

### FIELD

Embodiments of the present principles generally relate to semiconductor processing of semiconductor substrates.

### BACKGROUND

Scandium doped aluminum nitride (ScAlN) thin film layers may be used as active film layers in RF filters and acoustic wave filters. During manufacturing of the filters, defects may occur in the active film layer, reducing the performance of the filter device. The inventors have observed that traditional processes used to form the filters cause high numbers of surface cone defects in the active film layers and mis-oriented grains which substantially reduce the performance of the filters.

Accordingly, the inventors have provided methods and structures for producing high quality active film layers, dramatically improving the performance of filters and other structures that incorporate active film layers.

### SUMMARY

Methods and structures for improving the crystal quality of active film layers are provided herein.

In some embodiments, a method for forming a film stack for a piezoelectric device may comprise depositing a first seed layer on a substrate, depositing an intermediate film layer on the first seed layer where the intermediate film layer includes a first layer of a first material and a second layer of a second material that is different from the first material, depositing a second seed layer on the intermediate film layer, and depositing an piezoelectric layer on the second seed layer.

In some embodiments, the method may further include a first seed layer and a second seed layer that are different materials, a first material that is an oxide material and a second material that is a metal material, a first material that is a first metal material and a second material that is a second metal material, a first metal material that is titanium and a second metal material that is platinum, a first metal material that is titanium and a second metal material that is tungsten, a first seed layer and a second seed layer that are aluminum, aluminum nitride, aluminum oxide, or silicon nitride, a piezoelectric film layer that is scandium doped aluminum nitride of approximately 30% scandium or greater, an intermediate film layer that is deposited at a temperature of approximately 300 degrees Celsius to approximately 400 degrees Celsius, a piezoelectric film layer that is deposited at a temperature of less than 400 degrees Celsius, depositing multiple layers of the intermediate film layer on the substrate prior to depositing the second seed layer, a piezoelectric film layer that has a full width half maximum (FWHM) of 1.2 degrees or less, and/or a first material is silicon oxide.

In some embodiments, a film stack for a piezoelectric device may comprise a first seed layer on a substrate, an intermediate film layer on the first seed layer where the intermediate film layer includes a first layer of a first material and a second layer of a second material that is different from the first material, a second seed layer on the intermediate film layer, and a piezoelectric film layer on the second seed layer.

In some embodiments, the film stack may further include a first material that is an oxide material and a second material that is a metal material or a first material that is a first metal material and a second material that is a second metal material, a piezoelectric film layer that is scandium doped aluminum nitride of approximately 30% scandium or greater with a full width half maximum (FWHM) of 1.2 degrees or less, and/or a first seed layer and a second seed layer that are aluminum, aluminum nitride, aluminum oxide, or silicon nitride.

In some embodiments, a non-transitory, computer readable medium having instructions stored thereon that, when executed, cause a method for forming a film stack for a piezoelectric device to be performed, the method may comprise depositing a first seed layer on a substrate, depositing an intermediate film layer on the first seed layer where the intermediate film layer includes a first layer of a first material and a second layer of a second material that is different from the first material, depositing a second seed layer on the intermediate film layer, and depositing a piezoelectric film layer on the second seed layer.

In some embodiments, the method of the non-transitory, computer readable medium may further include a first material that is an oxide material and a second material that is a metal material or a first material that is a first metal material and a second material that is a second metal material, and/or an intermediate film layer that is deposited at a temperature of approximately 300 degrees Celsius to approximately 400 degrees Celsius.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method for forming a film stack for a piezoelectric device in accordance with some embodiments of the present principles.

FIG. 2 depicts a cross-sectional view of a substrate in accordance with some embodiments of the present principles.

FIG. 3 depicts a cross-sectional view of forming a first seed layer in accordance with some embodiments of the present principles.

FIG. 4 depicts a cross-sectional view of forming an intermediate film layer on a first seed layer in accordance with some embodiments of the present principles.

FIG. 5 depicts a cross-sectional view of forming an intermediate film layer with multiple pairs of layers in accordance with some embodiments of the present principles.

FIG. 6 depicts a cross-sectional view of forming a second seed layer on an intermediate film layer in accordance with some embodiments of the present principles.

FIG. 7 depicts a cross-sectional view of forming a piezoelectric film layer on a second seed layer to form a film stack in accordance with some embodiments of the present principles.

FIG. 8 depicts a top-down view of a surface showing cone defects per area on a piezoelectric film layer in accordance with some embodiments of the present principles.

FIG. 9 depicts an integrated tool in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and structures provide high-quality active film layers with minimal surface and grain orientation defects in the active film layer for applications in piezoelectric devices, such as, microelectromechanical systems (MEMS), microphones, RF filters and the like. The present techniques improve the quality of the active film layers by using underlying layers including a first seed layer, intermediate layers comprised of multiple materials in each layer, and a second seed layer. The active film layer produced by the methods has good crystal orientation with substantially smaller full-width-half-maximums (FWHMs). The present processes also have the advantage of being performed at lower process temperatures than traditional processes. The lower temperatures allow the present techniques to be used with low thermal budget processes. The techniques have the benefit of providing good surface and crystal orientation for plasma vapor deposition (PVD) sputtered scandium aluminum nitride active film stacks with scandium percentages above 30%.

The active film layer is deposited on intermediate layers with differing compositions of multiple metals and/or oxides. The metals may include, but are not limited to, titanium, platinum, and/or tungsten and the like. In some embodiments, the active film layer may be scandium doped with aluminum nitride (ScAlN). Controlling defects of ScAlN is substantially more difficult to accomplish compared to undoped aluminum nitride. The present methods achieve both low film dislocation densities (FWHMs of less than 1.5 degrees) and good film surface quality with few to none mis-oriented grains (MOGs) for ScAlN active layers. The present techniques improve the interfaces between metal and/or oxide materials and the active layer through the insertion of thin seed layers both under the metal and/or oxide materials and between the metal materials and the active film layer when deposited on a silicon or silicon dioxide substrate. The seed layers improve both the metal or oxide layer crystal quality and also the active film layer quality. In some embodiments, the oxide materials may include silicon oxide and the like. In some embodiments, the metal materials may include titanium, platinum, and/or tungsten and the like. In some embodiments, the seed layers may include, but are not limited to, aluminum nitride, aluminum, silicon nitride, and/or aluminum oxide, and the like.

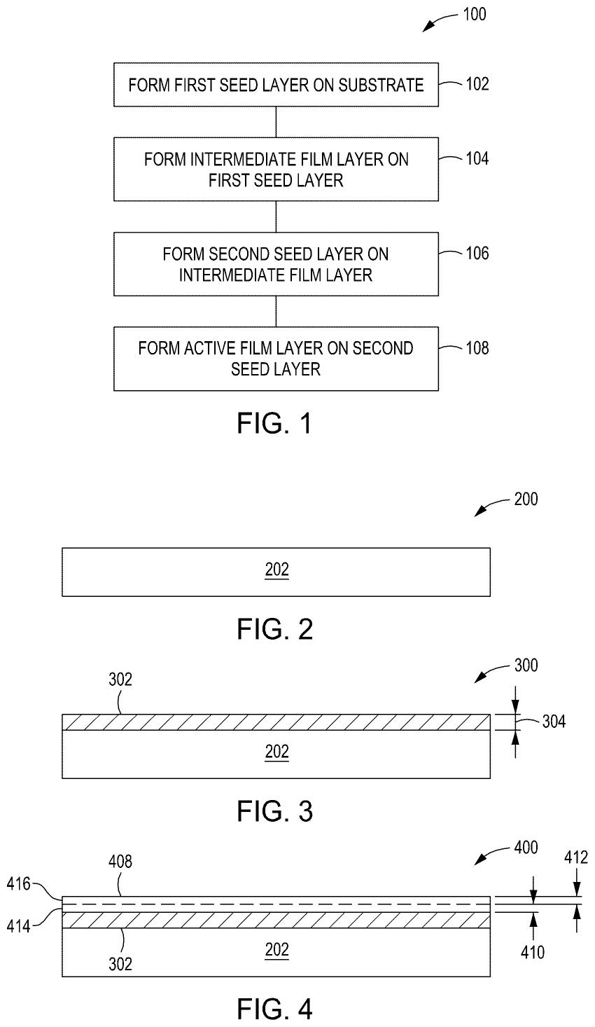

FIG. 1 is a method 100 for forming a film stack for a piezoelectric device such as, for example, a film stack with an active film layer or piezoelectric film layer of scandium doped aluminum nitride in accordance with some embodiments.

References to FIGS. 2-9 may be made during discussions of the method 100. A substrate 202 as depicted in a view 200 of FIG. 2 may be formed of, for example, silicon or silicon dioxide and the like which is not meant to be limiting. If the substrate 202 has been exposed to the environment, the substrate 202 may be degassed before beginning the film stack formation process. In block 102, a first seed layer 302 is formed on the substrate 202 as depicted in a view 300 of FIG. 3. In some embodiments, a thickness 304 of the first seed layer 302 may be from approximately 10 nm to approximately 200 nm. In some embodiments, the first seed layer 302 may have a thickness 304 of approximately 30 nm. The first seed layer 302 may be comprised of, but not limited to, aluminum, aluminum nitride, aluminum oxide, and/or silicon nitride and the like which may be deposited using a first deposition chamber such as, for example, a PVD deposition chamber. The selection of the material of the first seed layer 302 may be selected based on the material of the substrate and the material of the first layer 414 (see, FIG. 4 below) of the intermediate film layer 408. The material of the first seed layer 302 is selected to provide a better crystal lattice transition between the two different materials of the substrate 202 and first layer 414.

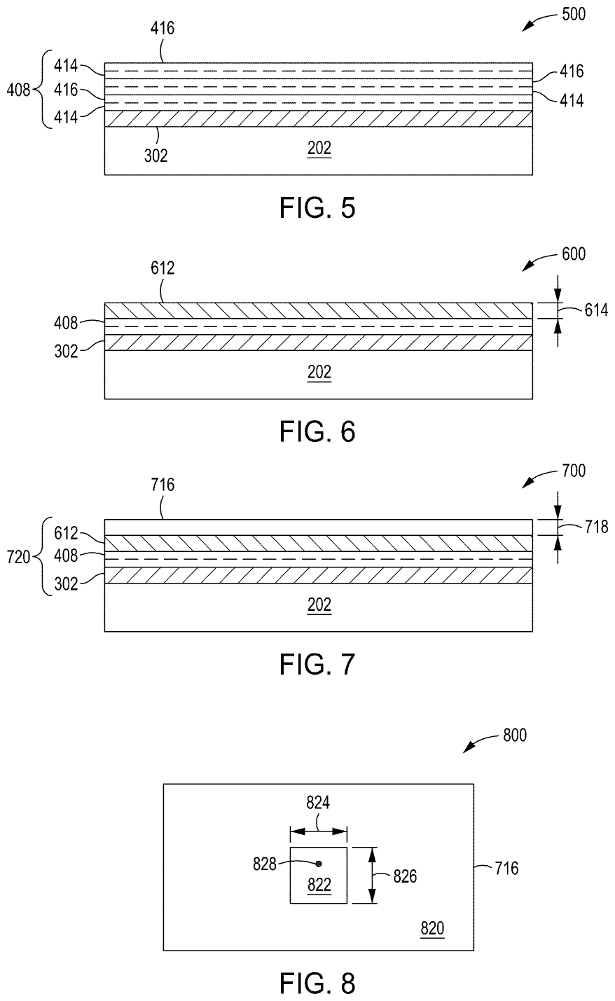

In block 104, an intermediate film layer 408 composed of, but not limited to, titanium, platinum, and/or tungsten and the like is formed on the first seed layer 304 as depicted in a view 400 of FIG. 4. The intermediate film layer 408 includes a first layer 414 of a first material and a second layer 416 of a second material different from the first material. The first layer 414 and the second layer 416 form a ‘pair’ that may be repeated in some embodiments of the intermediate film layer 408 (see view 500 of FIG. 5). In some embodiments, the intermediate film layer 408 may function as an acoustic reflector when used in some devices/systems. In some embodiments, the pair may be composed of an oxide layer and a metal layer. In some embodiments, the pair may be composed of a first metal layer and a second metal layer. In some embodiments, a thickness 410 of the first layer 414 (FIG. 4) of the intermediate film layer 408 may be from approximately 20 nm to approximately 100 nm and a thickness 412 of the second layer 416 may be from approximately 20 nm to approximately 100 nm. In some embodiments, the thickness 410 of the first layer 414 is approximately 50 nm and the thickness of the second layer is approximately 60 nm.

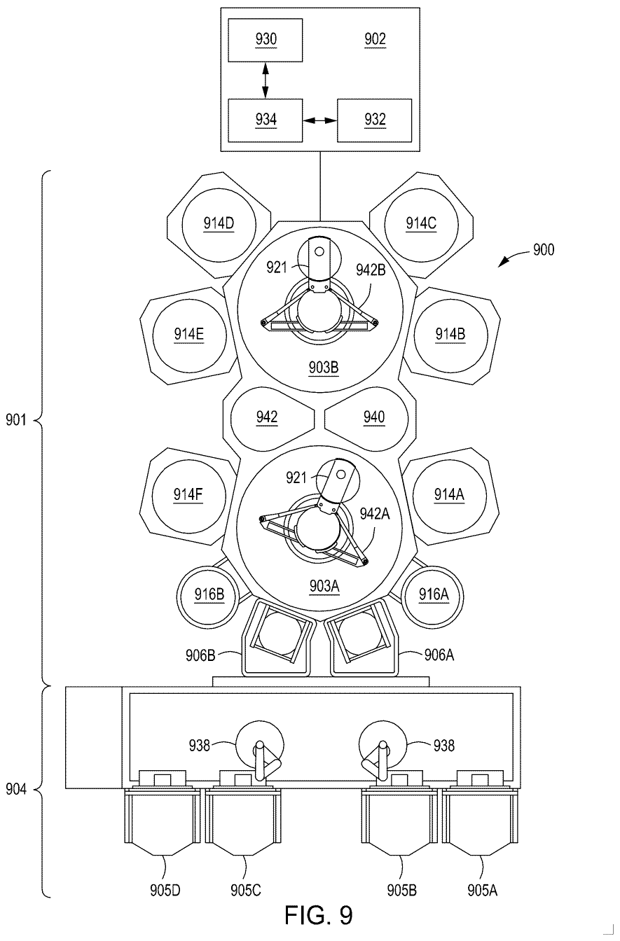

In some embodiments, to optimize the reduction of surface cone defects on a scandium doped aluminum nitride layer, the intermediate film layer 408 may be deposited with no vacuum break between the deposition of the first seed layer 302 and the deposition of the intermediate film layer 408 to eliminate any possible contamination or particles on the first seed layer 302 before deposition of the intermediate film layer 408. For example, the first deposition chamber and the second deposition chamber may be part of an integrated tool 900 as depicted in FIG. 9 that operates in a vacuum environment where substrates may be transferred between chambers without a vacuum break. The temperature of the intermediate film layer 408 deposition process can be used to control surface cone defects on the active film layer. In some embodiments, the intermediate film layer 408 is deposited at approximately 300 degrees Celsius to approximately 400 degrees Celsius. In some embodiments, the intermediate film layer 408 is deposited at approximately 400 degrees Celsius. Higher intermediate film layer deposition temperatures produce a higher quality intermediate film layer (e.g., lower FWHM), resulting in a reduction of surface cone defects on subsequently deposited active film layers. Higher quality intermediate film surfaces and crystal orientations produce higher quality active film surfaces (lower surface cone defects). For example, FWHMs of intermediate films deposited at approximately 400 degrees Celsius had improved surface quality than deposition of the intermediate films at approximately 300 degrees Celsius. With the improvement of intermediate film quality, the inventors have found that a deposition temperature of the approximately 400 degrees Celsius can provide a surface cone defect count of less than or equal to 10 defects per 100 microns² for the active film layer. For reference, FIG. 8 depicts a top-down view 800 of an active film surface 820 showing one surface cone defect 828 per area 822 on an active film layer 716 (see, FIG. 7) in accordance with some embodiments. As used herein, the area 822 is defined as a 100 micron² area (e.g., width 824=10 microns, length 826=10 microns, etc.).

In block 106, a second seed layer 612 is formed on the intermediate film layer 408 as depicted in a view 600 of FIG. 6. The addition of the second seed layer 612 enables a reduction of surface cone defects on subsequently deposited active film layers. In some instances, lower process temperatures may be needed to meet thermal budget constraints for device fabrication. The methods of the present principles enable device manufacturers to now produce low thermal budget devices of 400 degrees Celsius or less with low defect active film layers. In some embodiments, a thickness 614 of the second seed layer 612 may be from approximately 5 nm to approximately 150 nm. In some embodiments, a thickness 614 of the second seed layer 612 may be approximately 30 nm. The second seed layer 612 may be comprised of, but not limited to, aluminum, aluminum nitride, aluminum oxide, and/or silicon nitride and the like. In some embodiments, the second seed layer 612 can be deposited using the first deposition chamber which may be, for example, a PVD deposition chamber. The selection of the material of the second seed layer 612 may be selected based on the material of the second layer 416 (see, FIG. 5) of the intermediate film layer 408 and the material of the active film layer 716 (see FIG. 7). The material of the second seed layer 612 is selected to provide a better crystal lattice transition between the two different materials of the intermediate film layer 408 and the active film layer 716. In some embodiments, the material of the first seed layer 302 and the material of the second seed layer 612 may be different to optimize the crystal lattice transitions of the different materials of the intermediate film layer 408 to adjacent substrate material or adjacent active film layer material.

In some embodiments, to optimize the reduction of surface cone defects on an active film layer such as a scandium doped aluminum nitride layer, the second seed layer 612 may be deposited with no vacuum break between the deposition of intermediate film layer 408 and the deposition of the second seed layer 612 to eliminate any possible contamination or particles on the intermediate film layer 408 before deposition of the second seed layer 612. For example, the first deposition chamber and the second deposition chamber may be part of the integrated tool 900 as depicted in FIG. 9 that operates in a vacuum environment where substrates may be transferred between chambers without a vacuum break. The inventors believe that the immediate deposition of the second seed layer 612 retains the residual heat from the deposition of the intermediate film layer 408 in the second deposition chamber, and the residual heat may further facilitate in reducing surface cone defects of the active film layer. The second seed layer 612 functions as a transition layer between the intermediate film layer 408 and the active film layer 716 (see FIG. 7, described below) to facilitate in reducing surface cone defect counts for the active film layer 616 even when lower intermediate film layer 408 deposition temperatures are used (e.g., less than approximately 400 degrees Celsius).

In some embodiments, the substrate 202 may be cooled and exposed to an ambient environment. The substrate 202 would then be degassed before proceeding with the formation of the active film layer 716. If the substrate 202 is cooled within the integrated tool 900, no degassing process is needed before proceeding with the depositing of the active film layer. In block 108, the active film layer 716 or piezoelectric film layer is formed on the second seed layer 612. The first seed layer 302, the intermediate film layer 408, the second seed layer 612, and the active film layer 716 form a film stack 720 with improved piezoelectric performance. The active film layer 716 is deposited at a substrate temperature of less than 400 degrees Celsius (without pedestal heating) as depicted in the view 700 of FIG. 7. In some embodiments, the substrate temperature may be less than approximately 100 degrees Celsius. The low substrate temperature during deposition decreases stress nonuniformity of the film. The inventors have found that the active film layer crystal quality, especially with scandium doped aluminum nitride film, is mainly determined during the nucleation stage with high temperatures above 400 degrees Celsius, but the following bulk layer deposition temperatures can be much lower, which will not degrade the crystal quality. In some embodiments, the pedestal temperature can be set at approximately 25 degrees Celsius so as to not add any further heating to the substrate (which can be, for example, at a temperature of approximately 60 degrees Celsius to approximately 70 degrees Celsius after deposition of the second seed layer). Any heating of the substrate during PVD deposition of the active film layer is due to the deposition plasma.

In some embodiments, a thickness 718 of the active film layer 716 may be from approximately 5 nm to approximately 100 nm. In some embodiments, the active film layer 616 is comprised of a scandium doped aluminum nitride which may be deposited using a third deposition chamber which may be, for example, a PVD deposition chamber using a composite sputter target of approximately 30% or more scandium doped aluminum nitride. The third deposition chamber may be standalone or part of the integrated tool 900. The second seed layer 612 as discussed above provides a transition layer between the intermediate film layer 408 and the active film layer 716. Surface cone defects in the active film layer 716 may form during the nucleation stage of the deposition process. The inventors have found that deposition of the active film layer 716 on the second seed layer 612 causes fewer surface cone defects during the nucleation stage than deposition of active film layer 716 on the intermediate film layer 408 during the nucleation stage.

The inventors have discovered that along with temperature, vacuum breaks, and time between depositions, the combination of the thicknesses of the first seed layer 302, the intermediate film layer 408, and the second seed layer 512 can also affect the surface cone defect count for scandium doped aluminum nitride layers. In some embodiments, to further reduce the surface cone defect count for approximately 30% scandium doped aluminum nitride, the first seed layer 304 has a thickness of approximately 30 nm, the intermediate film layer 408 has a thickness of approximately 40 nm (e.g., approximately 20 nm for first layer and approximately 20 nm for second layer), and the second seed layer 612 has a thickness of approximately 30 nm.

The methods described herein may be performed in individual process chambers that may be provided in a standalone configuration or as part of a cluster tool, for example, the integrated tool 900 (i.e., cluster tool) described below with respect to FIG. 9. The advantage of using an integrated tool 900 is that there is no vacuum break between chambers and, therefore, no requirement to degas and pre-clean a substrate before treatment in a chamber. For example, in some embodiments the inventive methods discussed above may advantageously be performed in an integrated tool such that there are limited or no vacuum breaks between processes, limiting or preventing contamination of the substrate such as oxidation and the like. The integrated tool 900 includes a vacuum-tight processing platform 901, a factory interface 904, and a system controller 902. The processing platform 901 comprises multiple processing chambers, such as 914A, 913B, 914C, 914D, 914E, and 914F operatively coupled to a vacuum substrate transfer chamber (transfer chambers 903A, 903B). The factory interface 904 is operatively coupled to the transfer chamber 903A by one or more load lock chambers (two load lock chambers, such as 906A and 906B shown in FIG. 9).

In some embodiments, the factory interface 904 comprises at least one docking station 907, at least one factory interface robot 938 to facilitate the transfer of the semiconductor substrates. The docking station 907 is configured to accept one or more front opening unified pods (FOUP). Four FOUPS, such as 905A, 905B, 905C, and 905D are shown in the embodiment of FIG. 9. The factory interface robot 938 is configured to transfer the substrates from the factory interface 904 to the processing platform 901 through the load lock chambers, such as 906A and 906B. Each of the load lock chambers 906A and 906B have a first port coupled to the factory interface 904 and a second port coupled to the transfer chamber 903A. The load lock chamber 906A and 906B are coupled to a pressure control system (not shown) which pumps down and vents the load lock chambers 906A and 906B to facilitate passing the substrates between the vacuum environment of the transfer chamber 903A and the substantially ambient (e.g., atmospheric) environment of the factory interface 904. The transfer chambers 903A, 903B have vacuum robots 942A, 942B disposed in the respective transfer chambers 903A, 903B. The vacuum robot 942A is capable of transferring substrates 921 between the load lock chamber 906A, 906B, the processing chambers 914A and 914F and a cooldown station 940 or a pre-clean station 942. The vacuum robot 942B is capable of transferring substrates 921 between the cooldown station 940 or pre-clean station 942 and the processing chambers 914B, 914C, 914D, and 914E.

In some embodiments, the processing chambers 914A, 914B, 914C, 914D, 914E, and 914F are coupled to the transfer chambers 903A, 903B. The processing chambers 914A, 914B, 914C, 914D, 914E, and 914F may comprise, for example, an atomic layer deposition (ALD) process chamber, a physical vapor deposition (PVD) process chamber, chemical vapor deposition (CVD) chambers, annealing chambers, or the like. The chambers may include any chambers suitable to perform all or portions of the methods described herein, as discussed above, such as a molybdenum deposition chambers, aluminum nitride deposition chamber, a scandium doped aluminum nitride deposition chamber, and the like. In some embodiments, one or more optional service chambers (shown as 916A and 916B) may be coupled to the transfer chamber 903A. The service chambers 916A and 916B may be configured to perform other substrate processes, such as degassing, orientation, substrate metrology, cool down, and the like.

The system controller 902 controls the operation of the tool 900 using a direct control of the process chambers 914A, 914B, 914C, 914D, 914E, and 914F or alternatively, by controlling the computers (or controllers) associated with the process chambers 914A, 914B, 914C, 914D, 914E, and 914F and the tool 900. In operation, the system controller 902 enables data collection and feedback from the respective chambers and systems to optimize performance of the tool 900. The system controller 902 generally includes a Central Processing Unit (CPU) 930, a memory 934, and a support circuit 932. The CPU 930 may be any form of a general-purpose computer processor that can be used in an industrial setting. The support circuit 932 is conventionally coupled to the CPU 930 and may comprise a cache, clock circuits, input/output subsystems, power supplies, and the like. Software routines, such as a method as described above may be stored in the memory 934 and, when executed by the CPU 930, transform the CPU 930 into a specific purpose computer (system controller) 902. The software routines may also be stored and/or executed by a second controller (not shown) that is located remotely from the tool 900.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of forming a film stack for a piezoelectric device, the method comprising:
depositing a first seed layer on a substrate;
depositing an intermediate film layer on the first seed layer, wherein the intermediate film layer includes a first layer of a first material and a second layer of a second material that is different from the first material;
depositing a second seed layer on the intermediate film layer; and
depositing a piezoelectric film layer on the second seed layer.

2. The method of claim 1, wherein the first seed layer and the second seed layer are different materials.

3. The method of claim 1, wherein the first material is an oxide material and the second material is a metal material.

4. The method of claim 1, wherein the first material is a first metal material and the second material is a second metal material.

5. The method of claim 4, wherein the first metal material is titanium and the second metal material is platinum.

6. The method of claim 4, wherein the first metal material is titanium and the second metal material is tungsten.

7. The method of claim 1, wherein the first seed layer and the second seed layer are aluminum, aluminum nitride, aluminum oxide, or silicon nitride.

8. The method of claim 1, wherein the piezoelectric film layer is scandium doped aluminum nitride of approximately 30% scandium or greater.

9. The method of claim 1, wherein the intermediate film layer is deposited at a temperature of approximately 300 degrees Celsius to approximately 400 degrees Celsius.

10. The method of claim 1, wherein the piezoelectric film layer is deposited at a temperature of less than 400 degrees Celsius.

11. The method of claim 1, further comprising:
depositing multiple layers of the intermediate film layer on the substrate prior to depositing the second seed layer.

12. The method of claim 1, wherein the piezoelectric film layer has a full width half maximum (FWHM) of 1.2 degrees or less.

13. The method of claim 1, wherein the first material is silicon oxide.

14. A film stack for a piezoelectric device, comprising:
a first seed layer on a substrate;
an intermediate film layer on the first seed layer, wherein the intermediate film layer includes a first layer of a first material and a second layer of a second material that is different from the first material;
a second seed layer on the intermediate film layer; and
a piezoelectric film layer on the second seed layer.

15. The film stack of claim 14, wherein the first material is an oxide material and the second material is a metal material or wherein the first material is a first metal material and the second material is a second metal material.

16. The film stack of claim 14, wherein the piezoelectric film layer is scandium doped aluminum nitride of approximately 30% scandium or greater and has a full width half maximum (FWHM) of 1.2 degrees or less.

17. The film stack of claim 14, wherein the first seed layer and the second seed layer are aluminum, aluminum nitride, aluminum oxide, or silicon nitride.

18. A non-transitory, computer readable medium having instructions stored thereon that, when executed, cause a method of forming a film stack for a piezoelectric device to be performed, the method comprising:
depositing a first seed layer on a substrate;
depositing an intermediate film layer on the first seed layer, wherein the intermediate film layer includes a first layer of a first material and a second layer of a second material that is different from the first material;
depositing a second seed layer on the intermediate film layer; and
depositing a piezoelectric film layer on the second seed layer.

19. The non-transitory, computer readable medium of claim 18, wherein the first material is an oxide material and the second material is a metal material or wherein the first material is a first metal material and the second material is a second metal material.

20. The non-transitory, computer readable medium of claim 18, wherein the intermediate film layer is deposited at a temperature of approximately 300 degrees Celsius to approximately 400 degrees Celsius.
